(19) United States
(12) Patent Application Publication
(10) Pub. No.: US 2011/0036399 A1
(43) Pub. Date: Feb. 17, 2011

(54) PROCESS FOR MAKING A MULTI-LAYER STRUCTURE HAVING TRANSPARENT CONDUCTIVE OXIDE LAYERS WITH TEXTURED SURFACE AND THE STRUCTURE MADE THEREBY

(75) Inventors: Yuting LIN, Taichung County (TW); Shihche HUANG, Chiayi City (TW); Wenkai HSU, Hsinchu County (TW)

Correspondence Address: SUGHRUE MION, PLLC, 2100 PENNSYLVANIA AVENUE, N.W., SUITE 800, WASHINGTON, DC, 20037, US

(73) Assignee: DU PONT APOLLO LTD., Hong Kong (CN)

(21) Appl. No.: 12/855,893

(22) Filed: Aug. 13, 2010

Related U.S. Application Data
(60) Provisional application No. 61/233,534, filed on Aug. 13, 2009.

(51) Int. Cl. H01L 31/0236; H01L 31/18

(52) U.S. Cl. 136/256; 438/71; 257/E31.13

(57) ABSTRACT

The present invention relates to a novel process for making a multi-layer structure having transparent conductive oxide (TCO) layers with a textured surface comprising forming a metal-rich TCO layer. The process of the present invention is particularly useful in the manufacture of photovoltaic cells. In the device made by the process of the present invention, the textured surface of TCO layers can maintain high roughness while the interface effects caused by the overetching of the TCO layers are eliminated.

### FIELD OF THE INVENTION

The present invention relates to a process for making a multilayer structure having transparent conductive oxide (TCO) layers with textured surface and the device made by the process.

### BACKGROUND OF THE INVENTION

Photovoltaics refers to the process of generating electrical power from light, particularly sunlight. Photovoltaics has become the most mature and promising technology for alternative energy and will keep growing for at least decades. The European Photovoltaic Industry Association (EPIA) reports that the global photovoltaic invests was grown 27% in 2007 and forecasts that the annual growth rate will reach 34% during 2010 to 2020.

Although thin-film photovoltaic technology has a relatively low efficiency in comparison with other major photovoltaic technologies such as crystalline silicon, it is intensively researched due to low cost and its potential for mass production. Normally, thin film photovoltaic devices require transparent conductive oxide (TCO) layers of low resistivity and high light transmission as electrodes. Different materials could be used to make a TCO layer. For example, indium tin Oxide (ITO) and tin oxide were commonly used. However, indium and tin are rare and their salts are usually toxic, and an ITO is unstable in high temperature. Thus, the ITO has been gradually replaced by other materials, for example, Al doped ZnO (AZO).

The TCO layer is preferred with a rough surface (normally called “textured surface”) to scatter the incident light and allow the light to pass through the device for multiple times. This enhances the energy conversion.

For the production of a TCO layer with textured surface, two methods are known in the art. In the first method, a TCO layer is directly formed by the growth of a rough film. This method is currently used to produce large-surface TCO layers by chemical vapor deposition (CVD). For example, EP 0 204 563 discloses a low temperature (60 to 350° C.) CVD process for forming a zinc oxide film by using an organozinc compound and water carried in an inert gas and the zinc oxide film formed by said process has a resistivity of about 5E-4 to 2.5E-3 ohm-cm.

The second method normally involves a two-step process. A smooth TCO layer is initially formed and an etching process is subsequently employed to roughen the surface of said TCO layer. In the second method, various metal oxides including complex metal oxide can be used. In the second method, the TCO films are generally produced by means of physical vapor deposition (PVD), particularly sputtering. In comparison with the first method, the electrical and optical properties of the TCO films made by the second method are significantly improved but the films are visually smooth at deposition and have no light scattering effect. In order to form a textured surface, a subsequent wet etching operation is required to form a textured surface.

For example, US 2008/0163917 disclosed a method for the production of a zinc oxide TCO layer on a substrate by reactive sputtering. The sputter comprises a hysteresis region and is characterized by employing specific process condition and using doped Zn target in which the doping content is less than 2.3 at-%. The films formed by said sputtering are subjected to a wet-chemical etching to rough the surface to an rms roughness of 30-300 nm.

Other means for roughing and texturizing TCO films by wet etching can be found in literatures. For example, US 2008/0296262 discloses a conveyor-type process to rough and texturize a ZnO layer by an etching medium following a cleaning liquid. The process is technically simple to implement and suitable for treating large scale ZnO layers of, e.g., up to 1 m².

However, due to the irregularity of the metal grains and the isotropic character of wet etching, local defects due to overetching are often found on the surface of TCO films texturized by wet-etching. The defects usually result in undesired effects between the TCO layer and the subsequent amorphous silicon layer, for example, reduction of adhesion strength between the interface or generation of voids. The above interface effects significantly decrease the efficiency and reliability of a photovoltaic device. Therefore, it is desirable to develop a process to reduce or eliminate the above disadvantageous effects.

### SUMMARY OF THE INVENTION

One of the objects of the invention is to provide a novel process for making a photovoltaic device without the above interface defects.

The process of the present invention comprises the steps of:

(a) providing a substrate,

(b) forming a first TCO layer on the substrate,

(c) forming a second TCO layer which is metal-rich on the first TCO layer,

(d) optionally forming a third TCO layer on the second TCO layer,

(e) etching to form a textured surface, and

(f) depositing an amorphous silicon layer on the textured surface,

wherein the etching stops at the second TCO layer.

Another object of the present invention is to provide a multi-layer structure which is useful in making a photovoltaic device. The multi-layer structure comprises:

(a) a substrate,

(b) a first TCO layer,

(c) a second TCO layer which is metal-rich, and

(d) optionally a third TCO layer,

wherein at least a portion of the second TCO layer and at least a portion of the third TCO layer, if exists, are etched so a textured surface is formed.

### BRIEF DESCRIPTION OF THE DRAWING

FIGS. 1(a) and (b) schematically show the prior art process for forming a TCO layer (100) with textured surface on a substrate (5). In FIG. 1(a), a TCO film (100) is deposited on a substrate. After a wet-etching process, the surface is rough but the TCO film may be overetched, as (105) in FIG. 1(b).

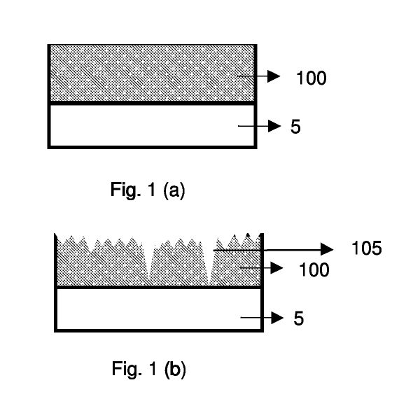

FIGS. 2(a) to (c) schematically show the process of the present invention. A metal-rich TCO layer (220) is deposited between two TCO layers (210, 230), as the structure shown in FIG. 2(b). Due to different etching rate to the metal rich TCO layer (220) and the third TCO layer (230), the surface of the multi-layer structure is texturized while the metal-rich TCO layer (220) serves as an etch stop and prevents overetching.

### DETAILED DESCRIPTION OF THE INVENTION

The present invention is illustrated below in detail by the embodiments with reference to the drawings, which are not intended to limit the scope of the present invention. It will be apparent that any modifications or alterations that can easily be accomplished by those having ordinary skill in the art fall within the scope of the disclosure of the specification.

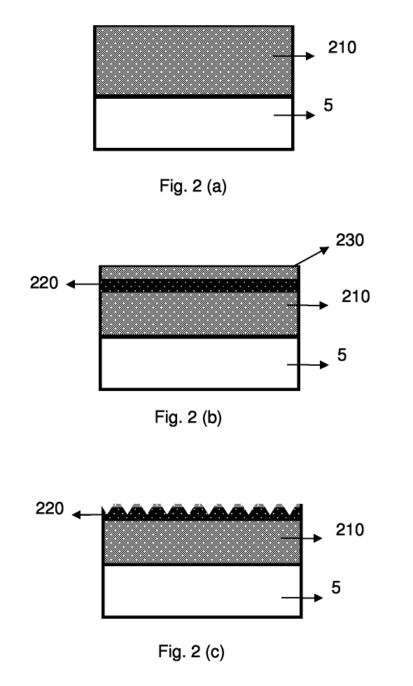

FIG. 2 illustrates the process of the present invention. As shown in FIG. 2(a), a first TCO layer is deposited on a substrate. The substrate of the present invention can be any substrate known to a skilled person in the art, such as glass, stainless steel sheet and polymer sheet.

Suitable materials for the first TCO layer can be any metal oxides including, but not limited to, oxides of Ag, Al, Cu, Cr, Zn, Mo, Wo, Ca, Ti, In, Sn, Ba, Ti or Ni. Preferred materials are oxides of Zn or Sn or BaTiO. The first TCO layer may be optionally doped with one or more metals selected from Al, Ga, Sb or other materials such as F and the dopants are in an amount of less than 5 wt %, preferably less than 2 wt % on the basis of the total weight of the first TCO layer. Examples of the doped metal oxides for the first TCO layer include ZnO:Al (AZO), ZnO:Ga (GZO), SnO2:Sb (ATO), SnO2:F (FTO) and BaTiO. The thickness of the first TCO can be adjusted to arrive desirable transparency and resistivity and is preferably 0.1 μm to 3 μm, more preferably 0.3 μm to 0.8 μm.

After the formation of the first TCO layer, a second TCO layer is formed thereon. The materials for the second TCO layer are selected from various metals or metal oxides doped with one or more metals. Preferred materials include ZnO doped with Al (AZO) or ZnO doped with Ga (GZO), and is optionally doped with one or more metals selected from Ag, Cu, Au, Mo, Wo, In, Ti, Sn, Ni or alike. The species and the thickness of the second TCO layer should be carefully selected to arrive desirable transparency, resistivity and etching selectivity.

The amount of dopants in the second layer can be adjusted and is preferably 10 wt % to 80 wt %, more preferably 20 wt % to 50 wt % on the basis of the total weight of the second layer. Higher metal or dopant contents normally result in higher resistance to chemical etching by acids, i.e., result in higher etching selectivity. However, Higher metal or dopant contents might also result in the decrease of transparency. Thus, the second TCO layer is normally as thin as possible to meet the transparency requirement. The thickness of the second TCO layer is preferably less than 0.05 μm, more preferably less than 0.03 μm to meet the transparency requirement. Nevertheless, the second TCO layer should be capable of withstanding a subsequent etching process so a minimum thickness, preferably 0.001 μm and more preferably 0.02 μm, is required.

Preferably, a third TCO layer may be deposited on the second TCO layer. Suitable materials for the third TCO layer can be any metal oxides including, but not limited to, oxides of Ag, Al, Cu, Cr, Zn, Mo, Wo, Ca, Ti, In, Sn, Ba, Ti or Ni. Preferred materials are oxides of Zn or Sn, or BaTiO. The third TCO layer may be optionally doped with one or more metals selected from Al, Ga, Sb or other materials such as F and the dopants are in an amount of less than 10 wt %, preferably less than 5 wt %, more preferably less than 2 wt % on the basis of the total weight of the third layer. Examples of the doped metal oxides for the third TCO layer include ZnO:Al (AZO), ZnO:Ga (GZO), SnO2:Sb (ATO), SnO2:F (FTO) and BaTiO. The thickness of the third layer is not critical because the layer will be subjected to an etching process and at least a portion of the film will be removed from the structure. In a preferred embodiment, the thickness of the third TCO layer is in the range of 0.01 μm to 0.1 μm.

To achieve a textured surface of high roughness after the subsequent etching, the grain size of the metal oxides in the third layer should be controlled. Normally, when the grain size is larger, a rougher surface can be formed. Adjustment of grain size is a skilled known in the art. For example, one can adjust the ratio of the metal and reactive gas, the spacing or RF power of the sputter reactor to adjust the grain size. For the present invention, the grain size is preferably 0.2 μm to 2.0 μm and more preferably 0.5 μm to 1.0 μm.

After the formation of the third TCO layer, a multi-layer structure is completed (as shown in FIG. 2(b)). However, the surface of the structure is smooth and not able to scatter incident light. Therefore, the surface is required to be further texturized. Any techniques texturizing a TCO film can be employed and chemical etching is preferred due to its isotropic character. In a preferred embodiment of the invention, the texturizing is done by a wet etching process with diluted HCl (for example, 0.5% HCl). The textured surface is preferably has an rms roughness of 30 nm to 130 nm. It should be noted that the ratio of the etching rate to the third TCO layer and that to the second TCO layer is preferably in a range of 2:1 to 6:1 and more preferably 3:1 to 4:1.

After the formation of the textured surface, the multi-layer structure of the invention can be subjected to further processes to form a p-type-intrinsic-n-type (pin) amorphous silicon film thereon. The pin amorphous silicon film is normally formed by plasma enhanced chemical vapor deposition (PECVD). In comparison to conventional technique, the multi-layer structure of the present invention, due to its surface topography, greatly reduces the defects such as voids or cracks in the pin amorphous silicon film and increases the adhesion strength between the TCO layer and the pin amorphous silicon film.

### EXAMPLES

Three-target DC sputtering system was used to produce the multilayer structure of the present invention. AZO, silver and AZO targets were configured in sequence. The process chamber was under a vacuum of 1.6×10⁻⁵ Pa with 65 sccm Ar gas flow and no oxygen. The DC power for the AZO targets was set to 3.7 KW and that for the silver target was set to 3 KW. A glass substrate was loaded in the process chamber and an AZO-Ag-AZO sandwiched structure was deposited thereon. Subject the AZO-Ag-AZO structure to a wet bench with 0.5% diluted HCl for 5 minute. Textured surface of an rms roughness of about 100 nm was observed. No overetching was found.

What is claimed is:

1. A multi-layer structure comprising:
(a) a substrate,
(b) a first transparent conductive oxide (TCO) layer,
(c) a second TCO layer which is metal-rich, and
(d) optionally a third TCO layer,
wherein at least a portion of the second TCO layer and at least a portion of the third TCO layer, if exists, are etched to form a textured surface.

2. The multi-layer structure according to claim 1, wherein the second TCO layer comprises ZnO doped with Al (AZO) or ZnO doped with Ga (GZO), and is optionally doped with one or more metals selected from Ag, Al, Cu, Au, Mo, Wo, In, Ti, Sn or Ni.

3. The multi-layer structure according to claim 2, wherein the dopant in the second TCO layer is in an amount of 10 wt % to 80 wt %.

4. The multi-layer structure according to claim 3, wherein the dopant in the second TCO layer is in an amount of 20 wt % to 50 wt %.

5. The multi-layer structure according to claim 1, wherein the thickness of the second TCO layer is 0.001 μm to 0.05 μm.

6. The multi-layer structure according to claim 5, wherein the thickness of the second TCO layer is 0.02 μm to 0.03 μm.

7. The multi-layer structure according to claim 1, wherein the third TCO layer comprises oxides of a metal selected from Ag, Al, Cu, Cr, Zn, Mo, Wo, Ca, Ti, In, Sn or Ni, or ZnO:Al (AZO), ZnO:Ga (GZO), SnO2:Sb (ATO), SnO₂:F (FTO) or BaTiO.

8. The multi-layer structure according to claim 1, wherein the grain size of the third TCO layer is in a range of 0.2 μm to 2.0 μm.

9. The multi-layer structure according to claim 1, wherein the first TCO layer comprises oxides of a metal selected from Ag, Al, Cu, Cr, Zn, Mo, Wo, Ca, Ti, In, Sn or Ni, or ZnO:Al (AZO), ZnO:Ga (GZO), SnO2:Sb (ATO), SnO₂:F (FTO) or BaTiO.

10. The multi-layer structure according to claim 1, wherein the thickness of the first TCO layer is 0.1 μm to 3 μm.

11. The multi-layer structure according to claim 1, wherein the first TCO layer and the third TCO layer are of the same material.

12. A method for making a multi-layer structure comprising the steps of:
(a) providing a substrate,
(b) forming a first TCO layer on the substrate,
(c) forming a second TCO layer which is metal rich on the first TCO layer,
(d) optionally forming a third TCO layer on the second TCO layer,
(e) etching to form a textured surface wherein the etching stops at the second TCO layer.

13. The method according to claim 12, wherein the second TCO layer comprises ZnO doped with Al (AZO) or ZnO doped with Ga (GZO), and is optionally doped with one or more metals selected from Ag, Al, Cu, Au, Mo, Wo, In, Ti, Sn or Ni.

14. The method according to claim 13, wherein the dopant in the second TCO layer is in an amount of 10 wt % to 80 wt %.

15. The method according to claim 14, wherein the dopant in the second TCO layer is in an amount of 20 wt % to 50 wt %.

16. The method according to claim 12, wherein the thickness of the second TCO layer is 0.001 μm to 0.05 μm.

17. The method according to claim 16, wherein the thickness of the second TCO layer is 0.02 μm to 0.03 μm.

18. The method according to claim 12, wherein the third TCO layer comprises oxides of a metal selected from Ag, Al, Cu, Cr, Zn, Mo, Wo, Ca, Ti, In, Sn or Ni, or ZnO:Al (AZO), ZnO:Ga (GZO), SnO2:Sb (ATO), SnO₂:F (FTO) or BaTiO.

19. The method according to claim 12, wherein the first TCO layer comprises oxides of a metal selected from Ag, Al, Cu, Cr, Zn, Mo, Wo, Ca, Ti, In, Sn or Ni, or ZnO:Al (AZO), ZnO:Ga (GZO), SnO2:Sb (ATO) SnO₂:F (FTO) or BaTiO.

20. The method according to claim 12, wherein the first TCO layer and the third TCO layer are of the same material.

21. The method according to claim 12, wherein the TCO layers are formed by sputtering.

22. The method according to claim 21, wherein the steps (b) to (d) are conducted in a single sputtering tool.

23. The method according to claim 12, wherein the ratio of the etching rate to the third TCO layer to that to the second TCO layer is in a range of 2:1 to 6:1.

24. The method according to claim 12, wherein the etching is a wet-chemical etching with diluted HCl.
